(19) United States
(12) Patent Application Publication
(10) Pub. No.: US 2023/0326742 A1
(43) Pub. Date: Oct. 12, 2023

(54) DEPOSITION METHOD AND PROCESSING APPARATUS

(71) Applicant: Tokyo Electron Limited, Tokyo (JP)

(72) Inventors: Kiwamu ITO, Yamanashi (JP); Yamato TONEGAWA, Yamanashi (JP)

(21) Appl. No.: 18/192,186

(22) Filed: Mar. 29, 2023

(30) Foreign Application Priority Data
Apr. 12, 2022 (JP) 2022-065844

(51) Int. Cl. H01L 21/02; C23C 16/34; C23C 16/56; C23C 16/50

(52) U.S. Cl. CPC H01L 21/02175; H01L 21/02274; H01L 21/0228; C23C 16/342; C23C 16/56; C23C 16/50

(57) ABSTRACT

A deposition method includes preparing a substrate having a recess. The deposition method includes supplying a first gas onto the substrate to deposit a boron nitride film in the recess, the first gas including a boron-containing gas and a nitrogen-containing gas. The deposition method includes supplying a second gas onto the substrate to heat-treat the boron nitride film, the second gas being free of the boron-containing gas and including the nitrogen-containing gas.

### CROSS-REFERENCE TO RELATED APPLICATIONS

This patent application claims priority to Japanese Patent Application No. 2022-065844, filed Apr. 12, 2022, the contents of which are incorporated herein by reference in their entirety.

### TECHNICAL FIELD

The present disclosure relates to a deposition method and a processing apparatus.

### BACKGROUND

Techniques in which a deposition step and an etching step are alternately performed repeatedly to fill a recess in a substrate surface with a film are known (see, for example, Patent Document 1).

### RELATED-ART DOCUMENT

### Patent Document

[Patent Document 1] Japanese Unexamined Patent Application Publication No. 2019-33230

### SUMMARY

One aspect of the present disclosure relates to a deposition method. The deposition method includes preparing a substrate having a recess, and includes supplying a first gas onto the substrate to deposit a boron nitride film in the recess, the first gas including a boron-containing gas and a nitrogen-containing gas. The deposition method includes supplying a second gas onto the substrate to heat-treat the boron nitride film, the second gas being free of the boron-containing gas and including the nitrogen-containing gas.

### BRIEF DESCRIPTION OF THE DRAWINGS

FIG. 1 is a flowchart illustrating a deposition method according to one embodiment.

FIGS. 2A to 2C are cross-sectional views of a substrate used in the deposition method according to the embodiment.

FIG. 3 is a schematic view of a processing apparatus according to the embodiment.

FIG. 4 is a graph illustrating a change rate for a film thickness of a boron nitride film used before and after heat treatment.

FIG. 5 is a graph illustrating a ratio of B to N of the boron nitride film used before and after heat treatment.

FIG. 6 is a graph illustrating surface roughness (RMS) of the boron nitride film used before and after heat treatment.

### DETAILED DESCRIPTION

Non-limiting embodiments of the present disclosure will be described below with reference to the drawings. In the drawings, the same or corresponding members or components are denoted by the same or corresponding numerals, and accordingly, duplicate description thereof will be omitted.

[Deposition Method]

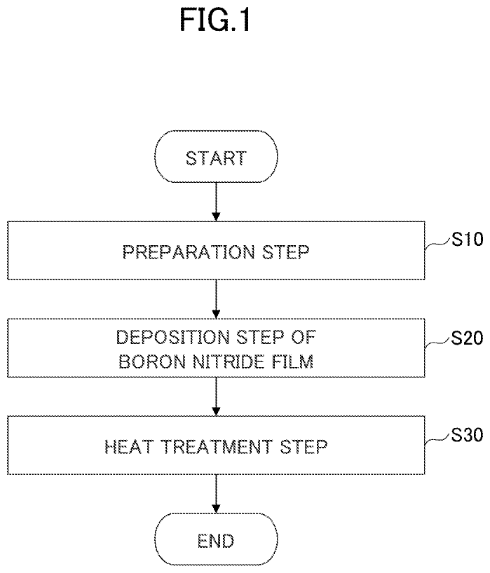

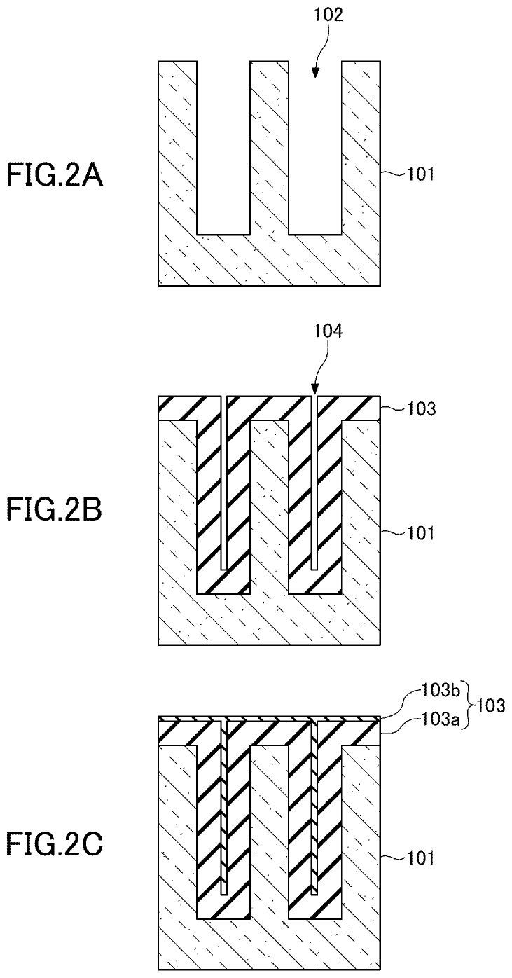

A deposition method according to one embodiment will be described with reference to FIGS. 1 to 2C. As illustrated in FIG. 1, the deposition method according to the embodiment includes a preparation step S10, a deposition step S20 of a boron nitride film, and a heat treatment step S30.

In the preparation step S10, as illustrated in FIG. 2A, a substrate 101 having a recess 102 is prepared. The substrate 101 may be a semiconductor substrate such as a silicon substrate. The recess 102 may include, for example, a trench or a hole. For example, an insulating film, such as a silicon oxide film or a silicon nitride film, may be formed on the surface of the recess 102.

The deposition step S20 is performed after the preparation step S10. In the deposition step S20, as illustrated in FIG. 2B, a first gas that includes a boron-containing gas and a nitrogen-containing gas is supplied to the substrate 101 to form a boron nitride film 103 in the recess 102. In the deposition step S20, a boron-rich boron nitride film 103 is formed. The boron-rich boron nitride film 103 refers to the boron nitride film 103 that is likely to be nitrided. The boron-rich boron nitride film 103 includes boron having dangling bonds in the film. When the boron nitride film 103 is deposited in the recess 102, there are cases where a space 104 may be formed in the recess 102. The space 104 includes, for example, a void or a seam.

The deposition step S20 may include maintaining the substrate 101 at a first temperature. The first temperature is preferably 300° C. or lower. In this case, the boron nitride film 103 that includes a high amount of boron with dangling bonds in the film can be deposited. In addition, the boron nitride film 103 having decreased surface roughness is likely to be deposited. The first temperature is more preferably 235° C. or lower. In this case, the boron nitride film 103 that includes a high amount of boron having the dangling bonds in the film can be further deposited.

The boron-containing gas that is included in the first gas may include, for example, diborone (B₂H₆) gas. The nitrogen-containing gas that is included in the first gas may include, for example, ammonia (NH₃) gas. A method of depositing the boron nitride film 103 is not particularly restricted. For example, the boron nitride film 103 can be deposited by atomic layer deposition (ALD) or chemical vapor deposition (CVD). Also, the first gas may include any other gas, such as an inert gas, except for the boron-containing gas and the nitrogen-containing gas. Examples of the inert gas include nitrogen (N₂) gas and argon (Ar) gas.

The heat treatment step S30 is performed after the deposition step S20. In the heat treatment step S30, a second gas, which is free of a boron-containing gas and includes a nitrogen-containing gas, is supplied to the substrate 101 to heat-treat the boron nitride film 103. With this approach, boron dangling bonds bond with nitrogen of the nitrogen-containing gas that is included in the second gas, and thus the boron is nitrided. For this reason, the volume of the boron nitride film 103 is increased, and thus the boron nitride film 103 expands. As a result, the space 104 is filled with the boron nitride film 103 so that the space 104 disappears. That is, embedding characteristics of the boron nitride film 103 in the recess 102 can be improved. In FIG. 2C, a portion 103a indicates a portion of the boron nitride film 103 obtained before the volume of the boron nitride film 103 increases, and a portion 103b indicates an expanded portion of the boron nitride film 103. In this case, the number of boron dangling bonds is reduced, and thus film qualities of the boron nitride film 103 are improved.

The heat treatment step S30 may include maintaining the substrate 101 at a second temperature. The second temperature is a temperature that is higher than the first temperature. The second temperature is preferably 550° C. or higher. In this case, the bonding of the boron dangling bonds with the nitrogen of the nitrogen-containing gas is progressed.

The heat treatment step S30 may include exposing the substrate 101 to a plasma that is formed from the second gas. In this case, in comparison to a case where the plasma is not used, the boron dangling bonds bond with the nitrogen of the nitrogen-containing gas at a low temperature, and thus is nitrided. For example, the heat treatment step S30 can be performed at the same temperature as that set in the deposition step S20.

The heat treatment step S30 may be performed at the processing chamber as in the deposition step S20, or may be performed at a different processing chamber than the processing chamber used in the deposition step S20.

An example of the nitrogen-containing gas that is included in the second gas includes ammonia gas. The second gas may include any other gas such as an inert gas, except for the nitrogen-containing gas. Examples of the inert gas include nitrogen gas and argon gas.

With this approach, the boron nitride film 103 can be embedded in the recess 102.

In the deposition method according to the embodiment, in the deposition step S20, a first gas that includes a boron-containing gas and a nitrogen-containing gas is first supplied to the substrate 101 to form the boron nitride film 103 in the recess 102. Then, in the heat treatment step S30, a second gas that is free of the boron-containing gas and includes the nitrogen-containing gas is supplied to the substrate 101 to heat-treat the boron nitride film 103. With this approach, boron having dangling bonds in the boron nitride film 103 as deposited in the deposition step S20, bond with the nitrogen of the nitrogen-containing gas included in the second gas as supplied in the heat treatment step S30, and thus the boron is nitrided. In such a manner, the volume of the boron nitride film 103 is increased, and thus expands. As a result, the space 104 is filled with the boron nitride film 103 so that the space 104 disappears. That is, embedding characteristics of the boron nitride film 103 in the recess 102 can be improved. In addition, the number of boron dangling bonds is reduced, and thus film qualities of the boron nitride film 103 are improved.

In the above embodiment, although a case where the deposition step S20 and the heat treatment step S30 are each performed once is described, the number of times the deposition step S20 and the heat treatment step S30 are performed is not limited thereto. For example, the recess 102 may be filled with the boron nitride film 103 by repeatedly performing the deposition step S20 and the heat treatment step S30, a plurality of times. In this case, the boron nitride film 103 is nitrided each time the boron nitride film 103 having a relatively thin is deposited, and thus boron dangling bonds are less likely to remain. Therefore, film qualities of the boron nitride film 103 are improved.

[Processing Apparatus]

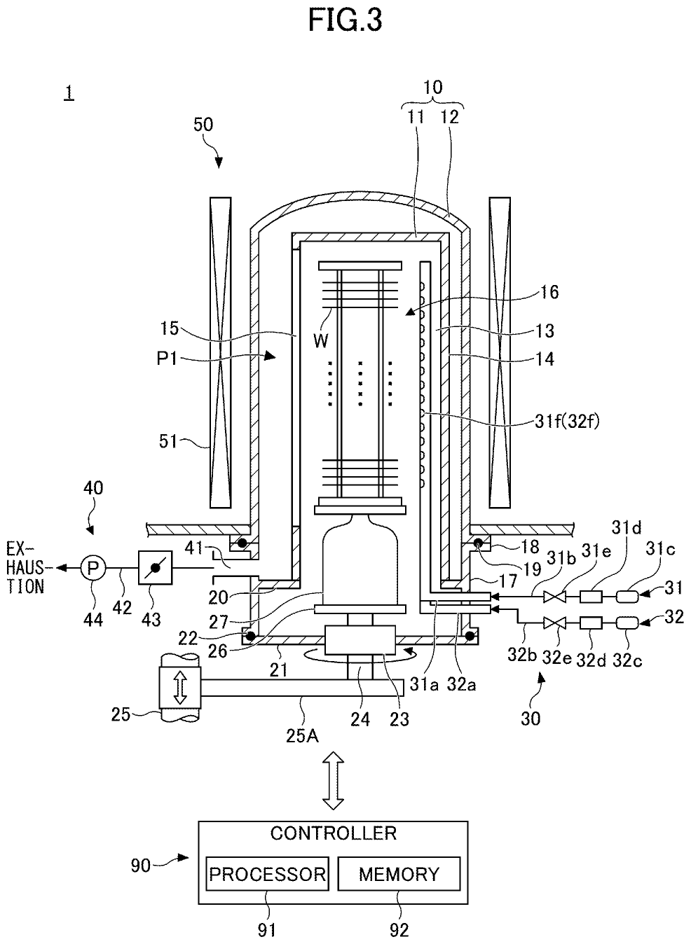

An example of a processing apparatus that can perform the deposition method according to the embodiment will be described with reference to FIG. 3. As illustrated in FIG. 3, a processing apparatus 1 is a batch-type apparatus that processes substrates W at the same time. Each substrate W may be, for example, a semiconductor wafer.

The processing apparatus 1 includes a processing chamber 10, a gas supply 30, an exhausting device 40, a heater device 50, and a controller 90.

An interior of the processing chamber 10 can be depressurized, and the processing chamber 10 accommodates the substrates W. The processing chamber 10 includes a cylindrical inner tube 11. A lower end of the inner tube 11 is open and the inner tube 11 has a ceiling. The processing chamber 10 also includes a cylindrical outer tube 12 that covers the outer side of the inner tube 11. The lower end of the outer tube 12 is open and the outer tube 12 has a ceiling. The inner tube 11 and the outer tube 12 are each formed of a heat-resistant material such as quartz, and are coaxially arranged to form a double tube structure.

The ceiling of the inner tube 11 is flat, for example. An accommodating portion 13 that accommodates a gas nozzle along the longitudinal direction (vertical direction) of the inner tube 11 is formed at one side of the inner tube 11. For example, a portion of the sidewall of the inner tube 11 protrudes outward to form a protruding portion 14, and the inside of the protruding portion 14 is formed as the accommodating portion 13.

A rectangular opening 15 is formed in the sidewall on the other side of the inner tube 11 along the longitudinal direction (vertical direction) of the inner tube 11 so as to face the accommodating portion 13.

The opening 15 is a gas exhaust port formed so as to be capable to exhaust the gas in the inner tube 11. The opening 15 has the same length as a length of a boat 16, or extends vertically, both upwards and downwards, to be longer than the length of the boat 16.

A lower end of the processing chamber 10 is supported by a cylindrical manifold 17 made, for example, of stainless steel. A flange 18 is formed on an upper end of the manifold 17, and a lower end of the outer tube 12 is provided to be supported on the flange 18. A sealing member 19, such as an O-ring, is interposed between the flange 18 and the lower end of the outer tube 12 so that an interior of the outer tube 12 is hermetically sealed.

An annular support 20 is provided at an inner wall of the upper portion of the manifold 17, and the lower end of the inner tube 11 is provided to be supported on the support 20. A cover 21 is hermetically attached to an opening at the lower end of the manifold 17 through the sealing member 22 such as an O-ring, so as to hermetically close the opening at the lower end of the processing chamber 10, that is, the opening of the manifold 17. The cover 21 is made of stainless steel, for example.

A rotation shaft 24, which rotatably supports the boat 16 through a magnetic fluid sealing portion 23, is provided at the central portion of the cover 21 to pass through the cover 21. A lower portion of the rotation shaft 24 is rotatably supported by an arm 25A of an elevation mechanism 25 that includes a boat elevator.

A rotation plate 26 is provided at an upper end of the rotation shaft 24, and the boat 16 that holds the substrates W is provided above the rotation plate 26, via a heated platform 27 made of quartz. With this arrangement, the cover 21 and the boat 16 are integrally moved up and down by raising and lowering the elevation mechanism 25. Thus, the boat 16 can be inserted into or removed from the processing chamber 10. The boat 16 can be accommodated by the processing chamber 10 and substantially horizontally holds a plurality of (for example, 50 to 150) substrates W, such that the substrates are spaced apart from one another when viewed in the vertical direction.

The gas supply 30 is configured to introduce various process gases, which are used in the above deposition method, into the processing chamber 10. The gas supply 30 includes a boron-containing gas supply 31 and a nitrogen-containing gas supply 32.

The boron-containing gas supply 31 includes a boron-containing gas supply line 31a (hereinafter also referred to as a gas supply line 31a) in the processing chamber 10, and includes a boron-containing gas supply path 31b (hereinafter also referred to as a gas supply path 31b) outside the processing chamber 10. A boron-containing gas source 31c, a mass flow controller 31d, and a boron-containing gas valve 31e are sequentially provided on the gas supply path 31b, when viewed from an upstream side to a downstream side in a gas flow direction. With this arrangement, a timing at which the boron-containing gas from the boron-containing gas source 31c is controlled by the boron-containing gas valve 31e, and further a flow rate of the boron-containing gas is adjusted to a predetermined flow rate by the mass flow controller 31d. The boron-containing gas flows into the gas supply line 31a via the gas supply path 31b, and then is discharged into the processing chamber 10 via the gas supply line 31a.

The nitrogen-containing gas supply 32 includes a nitrogen-containing gas supply line 32a (hereinafter also referred to as a gas supply line 32a) in the processing chamber 10, and includes a nitrogen-containing gas supply path 32b (hereinafter also referred to as a gas supply path 32b) outside the processing chamber 10. A nitrogen-containing gas source 32c, a mass flow controller 32d, and a nitrogen-containing gas valve 32e are sequentially provided on the gas supply path 32b, when viewed from the upstream side to the downstream side in the gas flow direction. With this arrangement, a timing at which the nitrogen-containing gas from the nitrogen-containing gas source 32c is controlled by the nitrogen-containing gas valve 32e, and further a flow rate of the nitrogen-containing gas is adjusted to a predetermined flow rate by the mass flow controller 32d. The nitrogen-containing gas flows into the gas supply line 32a via the gas supply path 32b, and then is discharged into the processing chamber 10 via the gas supply line 32a.

The boron-containing gas supply 31 and the nitrogen-containing gas supply 32 may each include a corresponding inert-gas supply path (not illustrated) via which a corresponding inert gas is introduced into the gas supply line 31a and the gas supply line 32a, respectively. On each of the inert-gas supply paths, an inert gas source, a mass flow controller, and an inert gas valve (which are not illustrated) may be provided in this order from the upstream side to the downstream side in the gas flow direction.

Each of the gas supply lines 31a and 32a is formed, for example, of silica. Each gas supply line is fixed to the manifold 17. Each of the gas supply lines 31a and 32a extends linearly and vertically at a location proximal to the inner tube 11. Also, each of the gas supply lines 31a and 32a is bent in an L-shape in the manifold 17, and then extends horizontally to pass through the manifold 17. The gas supply lines 31a and 32a are formed side by side along the circumferential direction of the inner tube 11, so as to have the same level.

Discharge ports 31f for a boron-containing gas are provided in a portion of the gas supply line 31a so as to correspond to the inner tube 11. Discharge ports 32f for a nitrogen-containing gas are provided in a portion of the gas supply line 32a so as to correspond to the inner tube 11. The discharge ports 31f are formed at predetermined intervals along an extension direction of the gas supply line 31a. Each discharge port 31f enables the gas to be discharged to flow in the horizontal direction. An interval between discharge ports 31f that are situated next to each other is set, for example, to be the same distance as an interval between substrates W that are to be held in the boat 16. When viewed in a height direction, each discharge port 31f is provided at a corresponding intermediate position between substrates W that are next to each other in the vertical direction. The discharge ports 32f are arranged as in the above discharge ports 31f. With this arrangement, each of the discharge ports 31f and 32f can efficiently supply the gas to a target area between substrates W that are situated next to each other.

The gas supply 30 may mix different gases to supply a gas mixture of the gases via one supply line. The gas supply lines 31a and 32a may have different shapes or arrangements. The gas supply 30 may be configured to supply any other gas, in addition to the boron-containing gas, the nitrogen-containing gas, and the inert gas.

The exhausting device 40 exhausts the gas that is discharged from the interior of the inner tube 11, through the opening 15. Also, the exhausting device 40 exhausts the gas that is discharged from a gas outlet 41, through a space P1 between the inner tube 11 and the outer tube 12. The gas outlet 41 is formed at the sidewall of the upper portion of the manifold 17 so as to be situated above the support 20. An exhaust passage 42 is connected to the gas outlet 41. A pressure regulating valve 43 and a vacuum pump 44 are sequentially provided on the exhaust passage 42, when viewed from the upstream side to the downstream side in the gas flow direction. The controller 90 controls the exhausting device 40 to operate the pressure regulating valve 43 and the vacuum pump 44, and thus the pressure in the processing chamber 10 is controlled by the pressure regulating valve 43, while the gas in the processing chamber 10 is suctioned by the vacuum pump 44.

The heater device 50 includes a cylindrical heater 51 that surrounds the outer tube 12 and is located radially outwardly from the outer tube 12. The heater 51 heats the entire outer periphery of the processing chamber 10 to heat each substrate W that is accommodated in the processing chamber 10.

The controller 90 may be implemented by a computer that includes one or more processors 91, a memory 92, an input-and-output interface (not illustrated), and an electronic circuit (not illustrated). The processor 91 may be implemented by any one or more of a central processing unit (CPU), an application specific integrated circuit (ASIC), a field programmable gate array (FPGA), a circuit with multiple discrete semiconductors, and the like. The memory 92 may include a volatile memory and a nonvolatile memory (for example, a compact disc, a digital versatile disc (DVD), a hard disk, a flash memory, and the like). The memory 92 stores a program that causes the processing apparatus 1 to operate, and stores a recipe such as a processing condition of substrate processing. By executing the program and the recipe that are stored in the memory 92, the processor 91 controls each component of the processing apparatus 1 to perform the above deposition method.

[Operation of Processing Apparatus]

The execution of the deposition method at the processing apparatus 1 according to the embodiment is described below.

The controller 90 controls the elevation mechanism 25 to transfer the boat 16, in which substrates W are held, into the processing chamber 10. Then, the cover 21 hermetically closes and seals the opening at the lower end of the processing chamber 10. Each substrate W is a corresponding substrate 101 having the recess 102 that is formed at the surface of the substrate 101.

Then, the controller 90 controls the gas supply 30, the exhausting device 40, and the heater device 50, so as to perform the deposition step S20. Specifically, the controller 90 controls the exhausting device 40 such that the pressure in the processing chamber 10 is decreased to a predetermined pressure. The controller 90 also controls the heater device 50 to adjust the temperature of each substrate to a predetermined temperature, so that the temperature of the substrate is maintained at a predetermined temperature. The predetermined temperature is, for example, 300° C. or lower. Subsequently, the controller 90 controls the gas supply 30 to supply a first gas, which includes the boron-containing gas and the nitrogen-containing gas, into the processing chamber 10. With this approach, a boron-rich boron nitride film 103 is deposited in the recess 102.

Then, the controller 90 controls the gas supply 30, the exhausting device 40, and the heater device 50, so as to perform the heat treatment step S30. Specifically, the controller 90 controls the exhausting device 40 to decrease the pressure in the processing chamber 10 to a predetermined pressure, and controls the heater device 50 to adjust the temperature of the substrate to a predetermined temperature so that the temperature of the substrate is maintained at the predetermined temperature. The predetermined temperature is, for example, 550° C. or higher. Subsequently, the controller 90 controls the gas supply 30 to supply a second gas, which is free of a boron-containing gas and includes a nitrogen-containing gas, into the processing chamber 10. With this approach, boron dangling bonds bond with nitrogen of the nitrogen-containing gas that is included in the second gas, and thus the boron is nitrided. Therefore, the volume of the boron nitride film 103 is increased so that the boron nitride film 103 expands. As a result, the space 104 is filled with the boron nitride film 103 so that the space 104 disappears. That is, embedding characteristics of the boron nitride film 103 in the recess 102 can be improved. In addition, the number of boron dangling bonds is reduced, and thus film qualities of the boron nitride film 103 are improved.

Then, the controller 90 increases the pressure in the processing chamber 10 to an atmospheric pressure, and decreases the temperature of the processing chamber 10 to a temperature at which transferring is enabled. Then, the controller 90 controls the elevation mechanism 25 to transfer the boat 16 out of the processing chamber 10.

As described above, the deposition method is performed at the processing apparatus 1 according to the embodiment, and thus the boron nitride film 103 can be embedded in the recess 102.

[Test Results]

Tests A and B were performed to confirm that the volume of the boron nitride film was increased in the heat treatment step S30 in the deposition method according to the embodiment. These tests will be described as follows.

In the test A, at the above processing apparatus 1, the deposition step S20 was performed under the condition A1 set forth below to thereby deposit a boron nitride film on a silicon substrate. Then, the film thickness of the deposited boron nitride film (before performing heat treatment) was measured by a spectroscopic ellipsometer. Then, at the processing apparatus 1, the heat treatment step S30 was performed under the condition A2 set forth below to thereby heat-treat the boron nitride film. Subsequently, after performing the heat treatment, the film thickness of the boron nitride film was measured by the spectroscopic ellipsometer. In addition, a change rate for the film thickness of the boron nitride film obtained before and after performing the heat treatment was calculated. The change rate for the film thickness was calculated by the following equation.

Change rate for film thickness=(film thickness after performing heat treatment−film thickness before performing heat treatment)/film thickness before performing heat treatment

(Condition A1)
Deposition method: CVD
First gas: a boron-containing gas, a nitrogen-containing gas, and an inert gas
Boron-containing gas: diborane gas
Nitrogen-containing gas: ammonia gas
Inert gas: nitrogen gas
Substrate temperature: 235° C.

(Condition A2)
Second gas: a nitrogen-containing gas and an inert gas
Nitrogen-containing gas: ammonia gas
Inert gas: nitrogen gas
Substrate temperature: 600° C.

In the test B, at the processing apparatus 1, the deposition step S20 was performed under the condition B1 set forth below to thereby deposit the boron nitride film on the silicon substrate. Then, the film thickness of the deposited boron nitride film (before performing heat treatment) was measured by the spectroscopic ellipsometer. Then, at the processing apparatus 1, the heat treatment step S30 was performed under the condition B2 set forth below to thereby heat-treat the boron nitride film. Subsequently, after performing the heat treatment, the film thickness of the boron nitride film was measured by the spectroscopic ellipsometer. In addition, a change rate for the film thickness of the boron nitride film obtained before and after performing the heat treatment was calculated. The change rate for the film thickness was calculated by the following equation.

Change rate for film thickness=(film thickness after performing heat treatment−film thickness before performing heat treatment)/film thickness before performing heat treatment

(Condition B1)
Deposition method: CVD
First gas: a boron-containing gas, a nitrogen-containing gas, and an inert gas
Boron-containing gas: diborane gas
Nitrogen-containing gas: ammonia gas
Inert gas: nitrogen gas
Substrate temperature: 300° C.

(Condition B2)
Second gas: a nitrogen-containing gas and an inert gas
Nitrogen-containing gas: ammonia gas
Inert gas: nitrogen gas
Substrate temperature: 700° C.

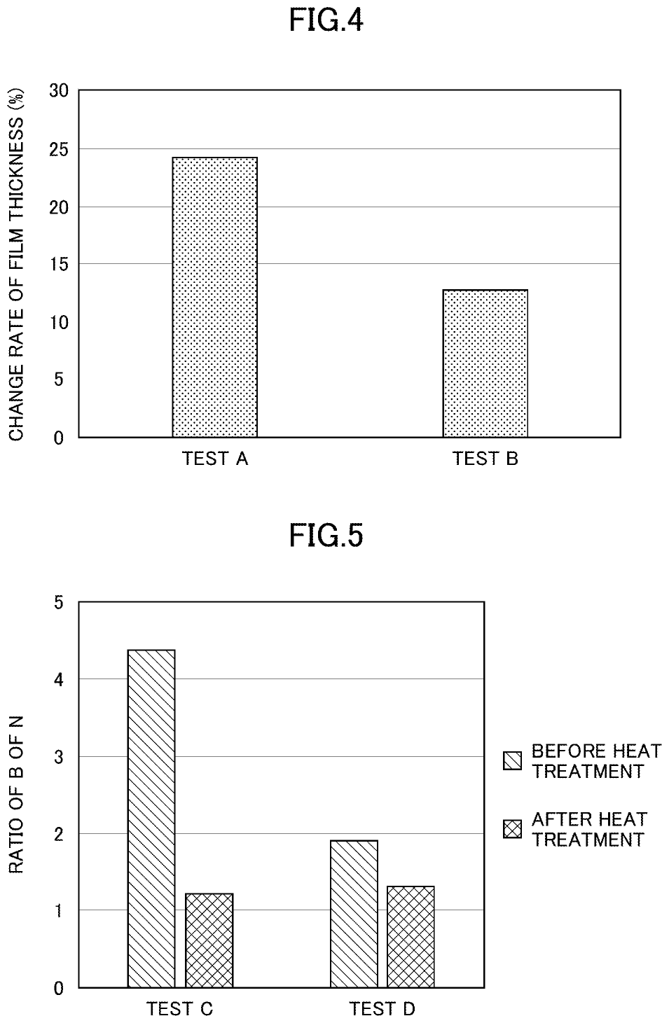

FIG. 4 is a graph illustrating the change rate for the film thickness of the boron nitride film obtained before and after performing heat treatment. In FIG. 4, each of the test A and the test B indicates the change rate (%) for the film thickness of the boron nitride film obtained before and after performing heat treatment.

As illustrated in FIG. 4, the change rate for the film thickness of the boron nitride film that was deposited in the test A was 24.3%, and the change rate for the film thickness of the boron nitride film deposited in the test B was 12.8%. From the result, it is apparent that the volume of the boron nitride film can be increased when the deposition step S20 and the heat treatment step S30 are performed in this order. The change rate for the film thickness of the boron nitride film in the test A is greater than the change rate in the test B. From the result, it is apparent that, in a case where the substrate temperature is set to 235° C. in the deposition step S20, the change rate for the film thickness of the boron nitride film is increased in comparison to a case where the substrate temperature is set to 300° C.

Hereinafter, tests C and D were performed to confirm the influence of variations in the substrate temperature during the deposition step S20 in the deposition method according to the embodiment, on the extent of progress of nitridation of boron present in the boron nitride film. These tests will be described as follows.

In the test C, at the above processing apparatus 1, the deposition step S20 was performed under the condition C1 set forth below to thereby deposit a boron nitride film on a silicon substrate. Then, the composition of the deposited boron nitride film (before performing heat treatment) was measured by X-ray photoelectron spectroscopy (XPS). Then, at the processing apparatus 1, the heat treatment step S30 was performed under the condition C2 set forth below to thereby heat-treat the boron nitride film. Subsequently, a composition of the boron nitride film obtained after performing the heat treatment was measured by the XPS. In addition, a ratio (hereinafter referred to as a ratio of B to N) of a boron concentration to a nitrogen concentration in the boron nitride film, before and after performing the heat treatment, was calculated.

(Condition C1)
Deposition method: CVD
First gas: a boron-containing gas, a nitrogen-containing gas, and an inert gas
Boron-containing gas: diborane gas
Nitrogen-containing gas: ammonia gas
Inert gas: nitrogen gas
Substrate temperature: 300° C.

(Condition C2)
Second gas: a nitrogen-containing gas and an inert gas
Nitrogen-containing gas: ammonia gas
Inert gas: nitrogen gas
Substrate temperature: 700° C.

In the test D, at the processing apparatus 1, the deposition step S20 was performed under the condition D1 set forth below to thereby deposit the boron nitride film on the silicon substrate. Then, the composition of the deposited boron nitride film (before performing heat treatment) was measured by the XPS. Then, at the processing apparatus 1, the heat treatment step S30 was performed under the condition D2 set forth below to thereby heat-treat the boron nitride film. Subsequently, the composition of the boron nitride film obtained after performing the heat treatment was measured by the XPS. In addition, a ratio of B to N in the boron nitride film before and after performing the heat treatment was calculated.

(Condition D1)
Deposition method: CVD
First gas: a boron-containing gas, a nitrogen-containing gas, and an inert gas
Boron-containing gas: diborane gas
Nitrogen-containing gas: ammonia gas
Inert gas: nitrogen gas
Substrate temperature: 550° C.

(Condition D2)
Second gas: a nitrogen-containing gas and an inert gas
Nitrogen-containing gas: ammonia gas
Inert gas: nitrogen gas
Substrate temperature: 700° C.

FIG. 5 is a graph illustrating the ratio of B to N in the boron nitride film obtained before and after the performing heat treatment. In FIG. 5, each of the test C and the test D indicates the ratio of B to N in the boron nitride film obtained before and after performing the heat treatment.

As illustrated in FIG. 5, in the test C, the ratio of B to N in the boron nitride film deposited before performing the heat treatment was 4.4, and the ratio of B to N in the boron nitride film deposited after performing the heat treatment was 1.2. In the test D, the ratio of B to N in the boron nitride film deposited before performing the heat treatment was 1.9, and the ratio of B to N in the boron nitride film deposited after performing the heat treatment was 1.3. From the result, it has been seen that the boron in the boron nitride film can be nitrided when the deposition step S20 and the heat treatment step S30 are performed in this order. In the test C, a change rate for the ration of B to N in the boron nitride film obtained before and after performing the heat treatment is greater than a change rate in the test D. From the result, it has been seen that, in a case where the substrate temperature is set to 300° C. in the deposition step S20, the change rate for the ratio of B to N in the boron nitride film is increased in comparison to a case where the substrate temperature is set to 550° C.

Tests E and F were performed to confirm influence of variations in the substrate temperature obtained in the deposition step S20 in the deposition method according to the embodiment, on surface roughness of the boron nitride film. These tests will be described as follows.

In the test E, at the processing apparatus 1, the deposition step S20 was performed under the condition C1 set forth above to form the boron nitride film on a silicon substrate. Then, the surface shape of the deposited boron nitride film (before performing heat treatment) was measured with scanning electron microscope (SEM) to calculate a value of surface roughness (RMS) of the boron nitride film. Then, at the processing apparatus 1, the heat treatment step S30 was performed under the condition C2 set forth above to heat-treat the boron nitride film. Subsequently, the surface shape of the boron nitride film after performing the heat treatment was measured by the SEM to calculate a value of the surface roughness (RMS) of the boron nitride film.

In the test F, at the processing apparatus 1, the deposition step S20 was performed under the condition D1 set forth above to form the boron nitride film on a silicon substrate. Then, the surface shape of the deposited boron nitride film (before performing heat treatment) was measured with the SEM to calculate a value of surface roughness (RMS) of the boron nitride film. Then, at the processing apparatus 1, the heat treatment step S30 was performed under the condition D2 set forth above to heat-treat the boron nitride film. Subsequently, the surface shape of the boron nitride film after performing the heat treatment was measured by the SEM to calculate a value of the surface roughness (RMS) of the boron nitride film.

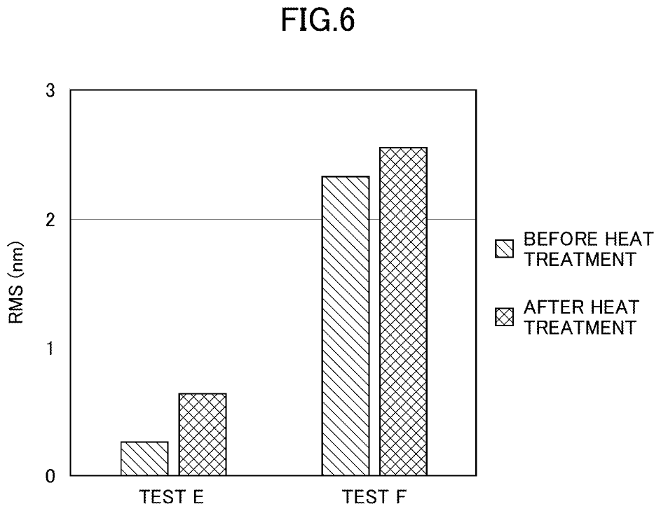

FIG. 6 is a graph illustrating the surface roughness (RMS) of the boron nitride film before and after performing the heat treatment. In FIG. 6, each of the test E and the test F indicates the RMS (nm) of the boron nitride film obtained before and after performing the heat treatment.

As illustrated in FIG. 6, in the test E, the RMS of the boron nitride film deposited before performing the heat treatment was 0.26, and the RMS of the boron nitride film deposited after performing the heat treatment was 0.64. In the test F, the RMS of the boron nitride film obtained before performing the heat treatment was 2.34, and the RMS of the boron nitride film obtained after performing the heat treatment was 2.56. From the result, it has been seen that, in a case where the substrate temperature is set to 300° C. in the deposition step S20, the surface roughness of the boron nitride film can be reduced in comparison to a case where the substrate temperature is set to 550° C.

The above embodiments are presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the scope of the disclosures. The accompanying claims and their equivalents are intended to cover such forms or modifications as would fall within the scope of the disclosures.

According to the present disclosure, embedding characteristics of a boron nitride film in a recess can be improved.

What is claimed is:

1. A deposition method comprising:
preparing a substrate having a recess;
supplying a first gas onto the substrate to deposit a boron nitride film in the recess, the first gas including a boron-containing gas and a nitrogen-containing gas; and
supplying a second gas onto the substrate to heat-treat the boron nitride film, the second gas being free of the boron-containing gas and including the nitrogen-containing gas.

2. The deposition method according to claim 1, wherein the depositing of the boron nitride film includes maintaining the substrate at a first temperature, and
wherein the heat-treating of the boron nitride film includes maintaining the substrate at a second temperature, the second temperature being higher than the first temperature.

3. The deposition method according to claim 2, wherein the first temperature is 300° C. or lower and the second temperature is 550° C. or higher.

4. The deposition method according to claim 1, wherein the heat-treating of the boron nitride film includes exposing the substrate to a plasma that is formed from the second gas.

5. The deposition method according to claim 1, wherein the heat-treating of the boron nitride film includes increasing a volume of the boron nitride film.

6. The deposition method according to claim 1, wherein the depositing of the boron nitride film and the heating of the boron nitride film are repeatedly performed a plurality of times.

7. The deposition method according to claim 1, wherein the boron-containing gas includes diborane gas, and the nitrogen-containing gas includes an ammonia gas.

8. A processing apparatus comprising:
a processing chamber;
a gas supply; and
a controller configured to:
cause a substrate having a recess to be accommodated in a processing chamber, and
control the gas supply to
supply a first gas onto the substrate, to deposit a boron nitride film in the recess, the first gas including a boron-containing gas and a nitrogen-containing gas, and
supply a second gas onto the substrate to heat-treat the boron nitride film, the second gas being free of the boron-containing gas and including the nitrogen-containing gas.
